(19) United States
(12) Patent Application Publication
(10) Pub. No.: US 2025/0370047 A1
(43) Pub. Date: Dec. 4, 2025

(54) PARALLEL KALMAN FILTER TECHNIQUES FOR ELECTRIFIED VEHICLE BATTERY SYSTEMS

(71) Applicant: FCA US LLC, Auburn Hills, MI (US)

(72) Inventors: Mostafa Shaben Mohamed Ahmed, Windsor (CA); Andrew White, Holly, MI (US)

(21) Appl. No.: 18/676,961

(22) Filed: May 29, 2024

(51) Int. Cl. G01R 31/367; G01R 31/387; H01M 50/51

(52) U.S. Cl. CPC G01R 31/367; G01R 31/387; H01M 50/51

(57) ABSTRACT

A state of charge (SOC) estimation method for a battery system of an electrified vehicle includes providing a first SOC estimator comprising a first Kalman filter and configured to estimate a first SOC of a first string of battery cells of the battery system having a first current flowing therethrough and providing a second SOC estimator comprising a second Kalman filter and configured to estimate a second SOC of a second string of battery cells of the battery system having a second current flowing therethrough, determining, in parallel, the first and second estimated SOCs using the first and second SOC estimators, respectively, determining a final SOC for the battery system based on the first and second estimated SOCs, and generating an output based on the determined final SOC for the electrified vehicle.

### FIELD

The present application generally relates to electrified vehicles and, more particularly, to parallel Kalman filter techniques for electrified vehicle battery systems.

### BACKGROUND

Electrified vehicles, such as battery electric vehicles (BEVs), include high voltage battery systems configured to power one or more electric motors for vehicle propulsion. Some high voltage electrified vehicles have two parallel battery packs or “strings” that are each capable of supplying energy to electric motor(s). Due to this parallel capability, different current can flow through each battery string. For example only, the electrified vehicle could be an 800V electrified vehicle having two parallel 400V battery strings. Each 400V battery string could further include, for example, 96-108 battery cells (e.g., ˜3.6V lithium-ion cells). Conventional state of charge (SOC) estimation systems use a single Kalman filter to perform SOC estimation in electrified vehicles, which is slow and could potentially result in reduced SOC estimation accuracy, particularly for larger battery systems having such large quantities of battery cells. Accordingly, while such conventional SOC estimation systems do work for their intended purpose, there exists an opportunity for improvement in the relevant art.

### SUMMARY

According to one example aspect of the invention, a state of charge (SOC) estimation system for a battery system of an electrified vehicle is presented. In one exemplary implementation, the SOC estimation system comprises a first SOC estimator comprising a first Kalman filter and configured to estimate a first SOC of a first string of battery cells of the battery system having a first current flowing therethrough and that collectively form a first battery pack rated at a first direct current (DC) voltage, a second SOC estimator comprising a second Kalman filter and configured to estimate a second SOC of a second string of battery cells of the battery system having a second current flowing therethrough and that collectively form a second battery pack rated at the first DC voltage, and a control system configured to, in parallel, determine the first and second estimated SOCs using the first and second SOC estimators, respectively, determine a final SOC for the battery system based on the first and second estimated SOCs, and generate an output based on the determined final SOC for the electrified vehicle.

In some implementations, the electrified vehicle is a battery electric vehicle (BEV) having a first electric motor configured to be powered by the first battery pack and to provide drive torque to a first axle and a second electric motor configured to be powered by the second battery pack and to provide drive torque to a different second axle. In some implementations, the first DC voltage is approximately 400V and the battery system is rated at a second DC voltage of approximately 800V.

In some implementations, the first and second battery packs are also connectable in series. In some implementations, the control system is further configured to connect the first and second battery packs in series to provide increased energy output to one of the first and second electric motors to provide increased torque at a respective one of the first and second axles. In some implementations, the control system is further configured to connect the first and second battery packs in series to perform recharging of the battery system via an 800V DC fast charging station.

According to another example aspect of the invention, an SOC estimation method for a battery system of an electrified vehicle is presented. In one exemplary implementation, the SOC estimation method comprises providing a first SOC estimator comprising a first Kalman filter and configured to estimate a first SOC of a first string of battery cells of the battery system having a first current flowing therethrough and that collectively form a first battery pack rated at a first DC voltage, providing a second SOC estimator comprising a second Kalman filter and configured to estimate a second SOC of a second string of battery cells of the battery system having a second current flowing therethrough and that collectively form a second battery pack rated at the first DC voltage, determining in parallel, by a control system of the electrified vehicle, the first and second estimated SOCs using the first and second SOC estimators, respectively, determining, by the control system, a final SOC for the battery system based on the first and second estimated SOCs, and generating, by the control system, an output based on the determined final SOC for the electrified vehicle.

In some implementations, the electrified vehicle is a BEV having a first electric motor configured to be powered by the first battery pack and to provide drive torque to a first axle and a second electric motor configured to be powered by the second battery pack and to provide drive torque to a different second axle. In some implementations, the first DC voltage is approximately 400V and the battery system is rated at a second DC voltage of approximately 800V.

In some implementations, the first and second battery packs are also connectable in series. In some implementations, the method further comprises connecting, by the control system, the first and second battery packs in series to provide increased energy output to one of the first and second electric motors to provide increased torque at a respective one of the first and second axles. In some implementations, the method further comprises connecting, by the control system, the first and second battery packs in series to perform recharging of the battery system via an 800V DC fast charging station.

Further areas of applicability of the teachings of the present application will become apparent from the detailed description, claims and the drawings provided hereinafter, wherein like reference numerals refer to like features throughout the several views of the drawings. It should be understood that the detailed description, including disclosed embodiments and drawings referenced therein, are merely exemplary in nature intended for purposes of illustration only and are not intended to limit the scope of the present disclosure, its application or uses. Thus, variations that do not depart from the gist of the present application are intended to be within the scope of the present application.

### BRIEF DESCRIPTION OF THE DRAWINGS

FIG. 1 is a functional block diagram of an electrified vehicle having an example state of charge (SOC) estimation system according to the principles of the present application;

FIG. 2 is a functional block diagram of an example architecture for the SOC estimation system according to the principles of the present application; and

FIG. 3 is a flow diagram of an example SOC estimation method for an electrified vehicle that utilizes parallel Kalman-type filters according to the principles of the present application.

### DESCRIPTION

As previously discussed, some high voltage electrified vehicles have two parallel battery packs or “strings” that are each capable of supplying energy to electric motor(s). Due to this parallel capability, different current can flow through each battery string. For example only, the electrified vehicle could be an 800V electrified vehicle having two parallel 400V battery strings. Each 400V battery string could further include, for example, 96-108 battery cells (e.g., ˜3.6V lithium-ion cells). Conventional state of charge (SOC) estimation systems use a single Kalman filter to perform SOC estimation in electrified vehicles, which is slow and could potentially result in reduced SOC estimation accuracy, particularly for larger battery systems having such large quantities of battery cells. Thus, while such conventional SOC estimation systems do work for their intended purpose, there exists an opportunity for improvement in the relevant art. Accordingly, improved SOC estimation systems and methods for electrified vehicles are presented herein.

These SOC estimation techniques utilize parallel separate Kalman-type filters for each battery string, regardless of the series/parallel state or connection of the battery strings. When connected in parallel, different currents can flow through each string and thus this approach will be much more accurate. Additionally, when connected in series, this approach will still be approximately twice as fast as conventional single Kalman filter SOC estimation. These techniques are particularly applicable to a two motor (i.e., one motor per axle) all-wheel drive (AWD) electrified vehicle, such as a battery electric vehicle (BEV) AWD pickup truck, where each 400V battery pack can be associated with one of the electric motors. In addition, the two battery strings can be connectable in series, such as for increased power output (e.g., front or rear) or for direct current (DC) fast charging (e.g., 800V DC fast charging).

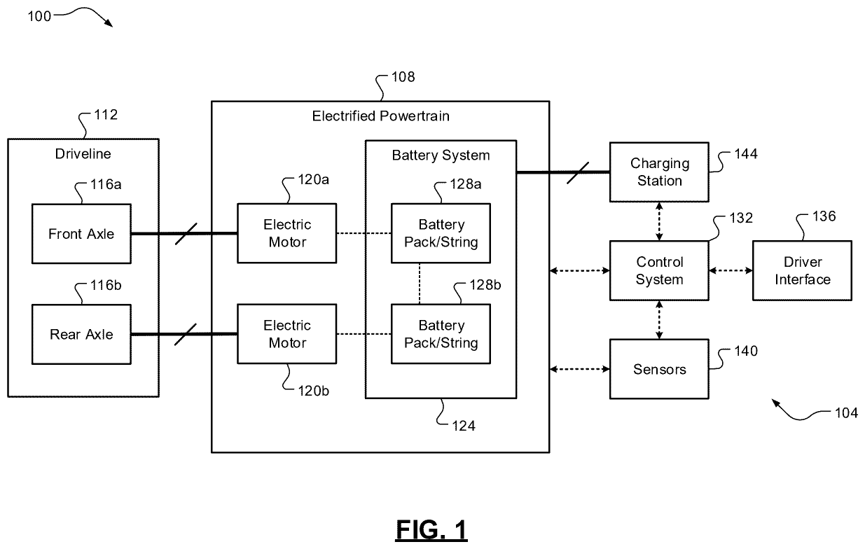

Referring now to FIG. 1, a functional block diagram of an electrified vehicle 100 having an SOC estimation system 104 according to the principles of the present application is illustrated. The electrified vehicle 100 generally comprises an electrified powertrain 108 configured to generate and transfer drive torque to a driveline 112 for vehicle propulsion. As shown, the driveline 112 includes a front axle 116a and a rear axle 116b (collectively, “axles 116”) that are separately connected to a first electric motor 120a and a second electric motor 120b (collectively, “electric motors 120”) of the electrified powertrain 108. It will be appreciated that there could also be transmissions or other torque transfer devices (not shown) arranged between the electric motors 120 and the axles 116. The electric motors 120 are powered by electrical energy from a high voltage battery system 124. The connection of the electric motor(s) 120 to the driveline 112 and to the battery system 124 can vary depending on an operating mode of the electrified powertrain 108.

In a parallel mode, the first electric motor 120a is powered by electrical energy provided by a first battery pack or string 128a and the second electric motor 120b is powered by electrical energy provided by a second battery pack or string 128b. In a series mode, the first and second battery packs or strings 128a and 128b (collectively, “battery packs 128” or “battery strings 128”) are connected to each other. In one exemplary implementation, each battery pack 128 is rated at ˜400V DC and the battery system 124 is rated at ˜800V DC. The series mode, for example, could be utilized to increase the power output of one of the electric motors 120a, 120b or for DC fast charging (e.g., 800V DC fast charging) of the battery system 124 via an external charging station 144 or another power source (e.g., AC wall power). It will be appreciated that there could also be an on-board or integrated charging module (OBCM/IDCM, not shown) that controls the recharging via the external charging station 144.

A controller or control system 132 controls operation of the electrified vehicle 100, which primarily includes controlling the electrified powertrain 108 to generate a desired amount of drive torque to satisfy a driver torque request from a driver interface 136 (e.g., an accelerator pedal). The control system 132 is also configured to control the operating mode of the electrified powertrain 108 (i.e., whether the battery packs 128 are connected in parallel or in series). The control system 132 is also configured to perform at least a portion of the SOC estimation techniques of the present application. This includes receiving measurements from a plurality of sensors 140, which are configured to measure operating parameters such as speeds, pressures, temperatures, and electrical parameters (voltage, current, etc.) of the electrified powertrain 108 and its components. The control system 132 is configured to implement two parallel Kalman-type filters (Kalman filters, extended Kalman filters, etc.).

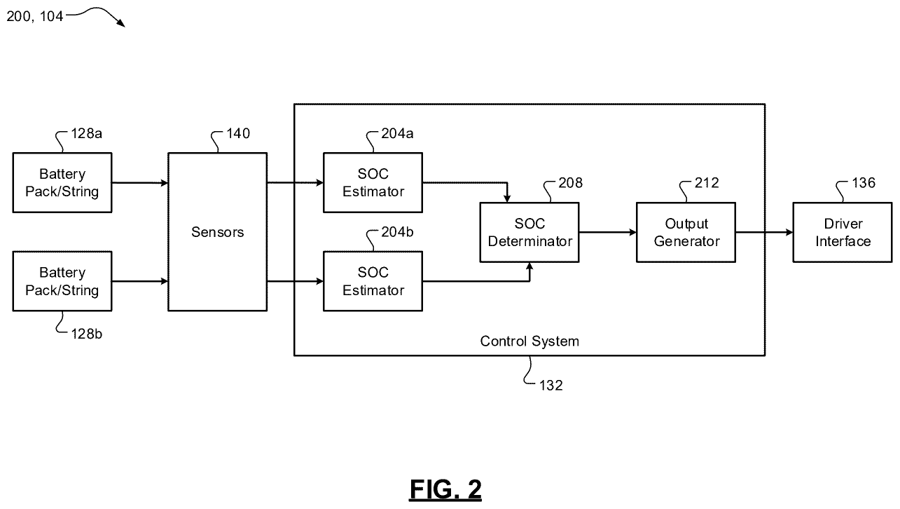

Referring now to FIG. 2 and with continued reference to FIG. 1, a functional block diagram of an example architecture 200 for the SOC estimation system 104 according to the principles of the present application is illustrated. As shown, the sensors 140 are configured to measure electrical parameters (voltage, current, etc.) of each of the battery packs/strings 128a and 128b. A first SOC estimator 204a is configured to implement a first Kalman-type filter to estimate the SOC of the first battery pack/string 128a and a second estimator 204b is configured to implement a separate Kalman-type filter to estimate the SOC of the second batter pack/string 128b. These SOC estimations are performable in parallel to decrease the SOC estimation time significantly. An SOC determinator 208 is then configured to determine a final SOC for the battery system 124 based on the first and second estimated SOCs of the first and second battery packs/strings 128a and 128b, respectively.

The SOC determinator 208 could, for example, take an average of these two SOC estimations to determine the final SOC for the battery system. It will be appreciated that other suitable techniques could be used, such as a weighted estimation or averaging. The control system 132 further comprises an output generator 212 configured to generate one or more outputs based on the final SOC of the battery system 124. This could include, for example, outputting the final SOC to the driver interface 136 for display to a driver of the electrified vehicle 100 (e.g., a current SOC % or a mileage range of the electrified vehicle). The final SOC could also be output or used for other vehicle functions, such as control of recharging of the battery system 124.

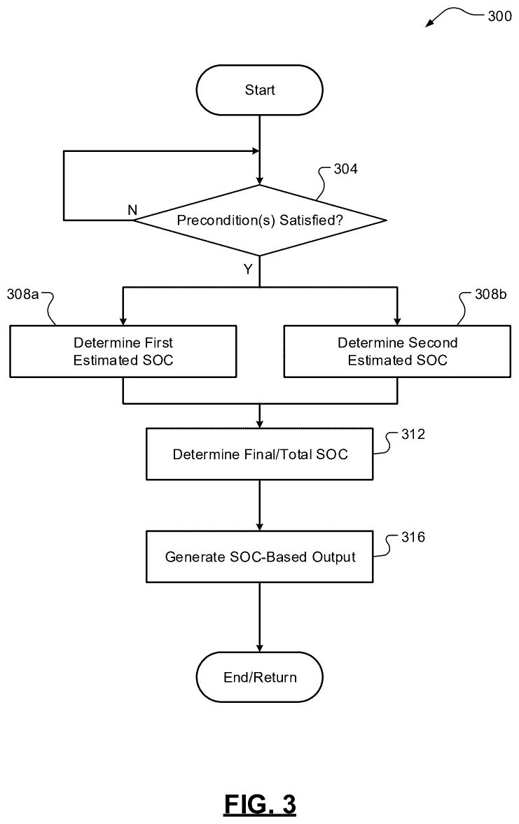

Referring now to FIG. 3 and with continued reference to FIGS. 1-2, a flow diagram of an example SOC estimation method 300 for an electrified vehicle that utilizes parallel Kalman-type filters according to the principles of the present application is illustrated. While the method 300 specifically references components of FIGS. 1-2, it will be appreciated that the method 300 could be applicable to any suitably configured electrified vehicle. The method 300 begins at 304 where the control system 132 optionally determines whether a set of one or more preconditions are satisfied. This could include, for example only, there being no malfunctions or faults present that would negatively impact or otherwise inhibit the operation of the techniques of the present application.

When false, the method 300 ends or returns to 304. When true, the method 300 proceeds to 308. At parallel 308a and 308b, the control system 132 uses the first SOC estimator (a first Kalman-type filter) to estimate the SOC of the first battery pack/string 128a and the second SOC estimator (a second Kalman-type filter) to estimate the SOC of the second battery pack/string 128b. At 312, the control system 132 determines the final SOC for the battery system 124 based on the first and second estimated SOCs. At 316, the control system 132 generates an output (e.g., a display for the driver interface 136) based on the final SOC. The method 300 then ends or returns to 304 for one or more additional cycles.

It will be appreciated that the terms “controller” and “control system” as used herein refer to any suitable control device or set of multiple control devices that is/are configured to perform at least a portion of the techniques of the present application. Non-limiting examples include an application-specific integrated circuit (ASIC), one or more processors and a non-transitory memory having instructions stored thereon that, when executed by the one or more processors, cause the controller to perform a set of operations corresponding to at least a portion of the techniques of the present application. The one or more processors could be either a single processor or two or more processors operating in a parallel or distributed architecture.

It should also be understood that the mixing and matching of features, elements, methodologies and/or functions between various examples may be expressly contemplated herein so that one skilled in the art would appreciate from the present teachings that features, elements and/or functions of one example may be incorporated into another example as appropriate, unless described otherwise above.

What is claimed is:

1. A state of charge (SOC) estimation system for a battery system of an electrified vehicle, the SOC estimation system comprising:
a first SOC estimator comprising a first Kalman filter and configured to estimate a first SOC of a first string of battery cells of the battery system having a first current flowing therethrough and that collectively form a first battery pack rated at a first direct current (DC) voltage;
a second SOC estimator comprising a second Kalman filter and configured to estimate a second SOC of a second string of battery cells of the battery system having a second current flowing therethrough and that collectively form a second battery pack rated at the first DC voltage; and
a control system configured to:
in parallel, determine the first and second estimated SOCs using the first and second SOC estimators, respectively;
determine a final SOC for the battery system based on the first and second estimated SOCs; and
generate an output based on the determined final SOC for the electrified vehicle.

2. The SOC estimation system of claim 1, wherein the electrified vehicle is a battery electric vehicle (BEV) having a first electric motor configured to be powered by the first battery pack and to provide drive torque to a first axle and a second electric motor configured to be powered by the second battery pack and to provide drive torque to a different second axle.

3. The SOC estimation system of claim 2, wherein the first DC voltage is approximately 400V and the battery system is rated at a second DC voltage of approximately 800V.

4. The SOC estimation system of claim 3, wherein the first and second battery packs are also connectable in series.

5. The SOC estimation system of claim 4, wherein the control system is further configured to connect the first and second battery packs in series to provide increased energy output to one of the first and second electric motors to provide increased torque at a respective one of the first and second axles.

6. The SOC estimation system of claim 4, wherein the control system is further configured to connect the first and second battery packs in series to perform recharging of the battery system via an 800V DC fast charging station.

7. A state of charge (SOC) estimation method for a battery system of an electrified vehicle, the SOC estimation method comprising:
providing a first SOC estimator comprising a first Kalman filter and configured to estimate a first SOC of a first string of battery cells of the battery system having a first current flowing therethrough and that collectively form a first battery pack rated at a first direct current (DC) voltage;
providing a second SOC estimator comprising a second Kalman filter and configured to estimate a second SOC of a second string of battery cells of the battery system having a second current flowing therethrough and that collectively form a second battery pack rated at the first DC voltage;
determining in parallel, by a control system of the electrified vehicle, the first and second estimated SOCs using the first and second SOC estimators, respectively;
determining, by the control system, a final SOC for the battery system based on the first and second estimated SOCs; and
generating, by the control system, an output based on the determined final SOC for the electrified vehicle.

8. The SOC estimation method of claim 7, wherein the electrified vehicle is a battery electric vehicle (BEV) having a first electric motor configured to be powered by the first battery pack and to provide drive torque to a first axle and a second electric motor configured to be powered by the second battery pack and to provide drive torque to a different second axle.

9. The SOC estimation method of claim 8, wherein the first DC voltage is approximately 400V and the battery system is rated at a second DC voltage of approximately 800V.

10. The SOC estimation method of claim 9, wherein the first and second battery packs are also connectable in series.

11. The SOC estimation method of claim 10, further comprising connecting, by the control system, the first and second battery packs in series to provide increased energy output to one of the first and second electric motors to provide increased torque at a respective one of the first and second axles.

12. The SOC estimation method of claim 10, further comprising connecting, by the control system, the first and second battery packs in series to perform recharging of the battery system via an 800V DC fast charging station.
